(19) United States
(12) Patent Application Publication
(10) Pub. No.: US 2002/0175267 A1
(43) Pub. Date: Nov. 28, 2002

(54) Direct imaging system for emission microscopy

(76) Inventors: Robert Malcolm Watson JR., San Leandro, CA (US); Haseeb R. Chaudhry, Berkeley, CA (US)

Correspondence Address: HAVERSTOCK & OWENS LLP, 162 NORTH WOLFE ROAD, SUNNYVALE, CA, 94086, US

(21) Appl. No.: 09/525,405

(22) Filed: Mar. 15, 2000

(51) Int. Cl. H01L 27/00

(52) U.S. Cl. 250/208.1

(57) ABSTRACT

A direct imaging system detects and locates photon emissions from an circuit which is known as the device under test. This direct imaging system includes an imaging head and stabilizers. The stabilizers securely couple the direct imaging system to a tester and prevents tester vibrations from reaching the imaging head. The imaging head includes an imager which detects and locates photon emissions from the device under test without passing the photon emissions through a series of lenses or needing to change lenses to magnify or reduce a viewable area of the device under test. The imager incudes a charge coupled device (CCD) sensor, a taper, and a micro lens array. The taper is optically coupled to the CCD sensor and optimized for use with the CCD sensor. The taper appropriately transmits photon emissions emitted from the device under test to the CCD sensor. The micro lens array is optically coupled to the taper and directly receives photon emissions from the device under test. The micro lens array directs these photon emissions to the taper for transmission to the CCD sensor. The taper includes fiber optic lines for transmitting the photon emissions to the CCD sensor in a virtually lossless manner. The imaging head is capable of appropriately positioning the imager relative to the device under test through a controller, guides, and a positioner. To magnify the resolution, the imager is preferably positioned closer to the device under test.

### FIELD OF THE INVENTION

The present invention relates to the field of detectors for analysis of emissions from electronic circuits. More particularly, the present invention relates to the field of detectors that analyze ultraviolet-to-infrared photon emissions by utilizing a charge coupled device sensor.

### BACKGROUND OF THE INVENTION

Detection devices that detect and locate photon emissions from an electrical circuit (a device under test) through charge coupled device (CCD) sensors are well known in the art. In order to provide meaningful results, these detection devices generally need to have focusing and enlargement capabilities. A series of lenses between the device under test and the CCD sensor is typically required to provide basic focusing and enlargement capabilities. Because of the distance between the device under test and the CCD sensor in these prior art detection devices, multiple lenses are typically required between the device under test and the CCD sensor to capture and direct photon emissions expelled by the device under test to the CCD sensor. Further, multiple lenses between the device under test and the CCD sensor are also required in order to adjust the magnification of the viewable area of the device under test to be inspected. Without using multiple lenses between the CCD sensor and the device under test, these detection devices can neither effectively detect nor locate photon emissions from the device under test.

These prior art detection devices which utilize lenses between the device under test and the CCD sensor suffer from various drawbacks. First, by utilizing multiple lenses between the device under test and the CCD sensor, the photon emissions that are represented by light waves which reach the CCD sensor must pass through multiple lenses. By their inherent nature, these lenses are not 100% efficient at passing and directing light. A certain amount of light waves are absorbed by these lenses or are misdirected. By passing through multiple lenses prior to reaching the CCD sensor, a significant number of light waves that represent photon emissions from the device under test are misguided and ultimately do not reach the CCD sensor. Because the light waves that represent the photon emissions from the device under test are often weak, forcing these light waves to pass through multiple lenses further decreases the sensitivity of these prior art detection devices. Thus, these prior art detection devices which utilize multiple lenses are inherently less efficient at detecting the photon emissions from the device under test compared to devices using a single lens or no lens.

Further, by utilizing lenses to focus the CCD sensor, these detection devices require substituting various lenses having different focal lengths in order to change an effective magnification of the device under test. Typically, changing lenses is accomplished by switching objectives. In order to achieve a proper focus once an objective is switched, the detection device must recalibrate the distance between the objective and the device under test. Further, the objective must also be re-positioned to view a desired portion of the device under test. Switching objectives while inspecting the device under test is a time consuming task. Accordingly, each time the effective magnification of the device under test in a prior art detection device is changed, several additional minutes are needed to complete the test. Further, by having multiple objectives, these prior art detection devices take up more space and add to the complexity of these devices.

Therefore, it is desirable to have an ability to detect and locate photon emissions from a circuit, without the need for a series of multiple lenses. It is also desirable have an ability to change focal magnification without changing objectives.

### SUMMARY OF THE INVENTION

The invention is a direct imaging system for detecting and locating photon emissions from a circuit which is known as the device under test. This direct imaging system includes an imaging head and stabilizers. The stabilizers securely couple the direct imaging system to a tester and prevents tester vibrations from reaching the imaging head. The imaging head includes an imager which detects and locates photon emissions from the device under test without passing the photon emissions through a series of lenses or needing to change lenses to magnify or reduce a viewable area of the device under test. The imager preferably incudes a charge coupled device (CCD) sensor, an optical taper, and a micro lens array. The CCD sensor comprises two dimensional CCD arrays to simultaneously detect photon emissions from at least a substantial portion of the device under test. The taper is optically coupled to the CCD sensor and optimized for use with the CCD sensor. The taper appropriately transmits photon emissions emitted from the device under test to the CCD sensor. The micro lens array is optically coupled to the taper and directly receives photon emissions from the device under test. The micro lens array directs these photon emissions to the taper for transmission to the CCD sensor. The taper includes fiber optic lines for transmitting the photon emissions to the CCD sensor in a virtually lossless manner. Preferably, the imaging head is capable of appropriately positioning the imager relative to the device under test through a controller, guides, and a positioner. To magnify the resolution, the imager is preferably positioned closer to the device under test.

### BRIEF DESCRIPTION OF THE DRAWINGS

FIG. 1A illustrates a schematic side view of internal elements an imager of a preferred embodiment of the present invention.

FIG. 1B illustrates a schematic side view of internal elements an alternate imager of the present invention.

FIG. 2 illustrates a schematic side view of an imaging head unit of the preferred embodiment.

FIG. 3 illustrates a schematic side view of the imaging head unit with a stabilizer configured to hold the imaging head unit within a tester according to the preferred embodiment.

FIG. 4 illustrates a block diagram showing a sample configuration of the preferred embodiment of the present invention.

FIG. 5 illustrates an LED light ring assembly according to the present invention.

### DETAILED DESCRIPTION OF THE PRESENT INVENTION

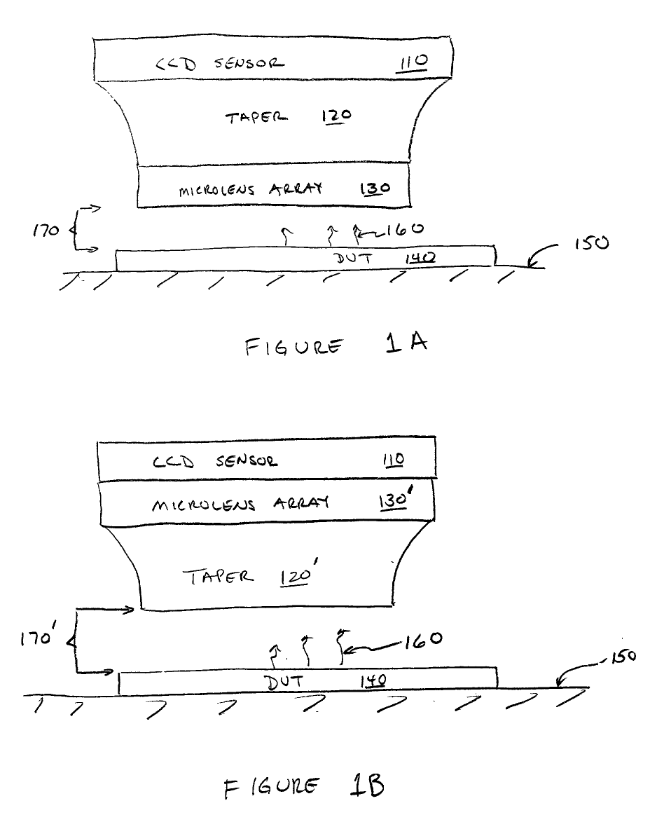

FIG. 1A illustrates a side view of an imager 100. The imager 100 preferably includes a charge coupled device (CCD) sensor 110, an optical taper 120, and a micro lens array 130. Preferably, the imager 100 is configured to detect and locate photon emissions 160 emitted from a device under test (DUT) 140 resting on a surface 150. The photon emissions 160, the surface 150, and the DUT 140 are shown for exemplary purposes only and are not intended to be part of the present invention. For the purposes of this specification, the DUT 140 is configured to operate such that the photon emissions 160 are emitted by the DUT 140 in response to the operation of the DUT 140.

The imager 100 detects and locates the photon emissions 160 from the DUT 140. Preferably, the CCD sensor 110 detects and locates photon emissions 160 that are emitted from at least a portion of the DUT 140. Specific elements and procedures of the imager 100 are described in detail below.

The CCD sensor 110 is preferably configured to include a two dimensional array of charge coupled devices. Preferably by having the CCD sensor 110 as a two dimensional sensor, the direct imaging system 100 is capable of simultaneously imaging either an entire area of the DUT 140 or just a portion of the DUT 140 (depending on the size of the DUT 140) for photon emissions emitted by the DUT 140. By simultaneously imaging the entire DUT 140, the CCD sensor 110 allows the direct imaging system 100 to complete the detection process in most cases well under one minute and in some cases in only twenty-five seconds. In this preferred embodiment, the CCD sensor 110 is manufactured by Sony Corporation having the model number ICX 038DLA. It will be apparent to those skilled in the art to utilize CCD sensors having different model numbers or from different manufacturers. In an alternate embodiment, the CCD sensor 110 comprises cooled charge coupled devices. By having the charge coupled devices within the CCD sensor 110 cooled, background noise is reduced and signal clarity is maximized.

The taper 120 is preferably coupled to the CCD sensor 110. The taper 120 preferably directs the photon emissions 160 to each of the discrete sensors within the CCD sensor 110 such that the photon emissions 160 are detected without the use of magnifying optics such as multiple lenses and the like. By utilizing the taper 120, the CCD 110 directly senses and locates the photon emissions 160 without requiring them to pass through any magnifying optics. Preferably, the taper 120 utilizes fiber optic lines to pass the photon emissions 160 from the DUT 140 to the CCD sensor 110. By utilizing fiber optic lines, signal loss due to the taper 120 is minimized and for practical purposes altogether eliminated.

Preferably, the taper 120 optimizes the resolution of the CCD sensor 110 over a predetermined area of the DUT 140. For example, by utilizing a larger area of the CCD sensor 110 over a smaller area of interest on the DUT 140, the taper 120 optimizes the resolution of the CCD sensor 110 to match the area of interest on the DUT 140.

The micro lens array 130 is preferably coupled to the taper 120. The micro lens array 130 receives the photon emissions 160 directly from the DUT 140 and transmits the photon emissions 160 to the taper 120. The micro lens array 130 directs the photon emissions 160 from the DUT 140 to one or more appropriate fiber optic lines of the taper 120.

As shown in FIG. 1A, the micro lens array 130 is preferably positioned at a predetermined distance 170 from the DUT 140. The predetermined distance 170 is selectively adjustable via the imaging system 100. As the predetermined distance 170 increases, a larger viewable area of the DUT 140 is observed by the imager 100. Similarly, as the distance 170 increases, the effective magnification of the DUT decreases which allows the same larger viewable area of the DUT 140 to be observed at a decreased resolution. Likewise, as the distance 170 decreases, there is a smaller viewable area of the DUT 140 is observed by the imager 100, an increased effective magnification of the DUT 140, and an increase in resolution of the DUT 140.

As shown in FIG. 1A, the imager 100 is capable of efficiently detecting and locating photon emissions 160 emitted from the DUT 140. The CCD sensor 110, the taper 120, and the micro lens array 130 are preferably optimized relative to each other. Further, the CCD sensor 110, the taper 120, and the micro lens array 130 also allow the imager 100 to increase or decrease magnification of the DUT 140 by merely changing the predetermined distance 170 and without requiring different lenses.

It will be apparent to one of ordinary skill in the art to which this invention pertains that the microlens array and the taper can be interchanged and still achieve the advantages of the present invention. FIG. 1B shows a side view of an alternate embodiment of the imager 100′ of the present invention. Elements which do not require changes for this alternate embodiment are illustrated with the same reference numerals. Modified elements are shown with a prime designation. The imager 100′ preferably includes a charge coupled device (CCD) sensor 110, an optical taper 120′, and a micro lens array 130′. Preferably, the imager 100′ is configured to detect and locate photon emissions 160 emitted from a device under test (DUT) 140 resting on a surface 150. The photon emissions 160, the surface 150, and the DUT 140 are shown for exemplary purposes only and are not intended to be part of the present invention. For the purposes of this specification, the DUT 140 is configured to operate such that the photon emissions 160 are emitted by the DUT 140 in response to the operation of the DUT 140.

The imager 100′ detects and locates the photon emissions 160 from the DUT 140. Preferably, the CCD sensor 110 detects and locates photon emissions 160 that are emitted from at least a portion of the DUT 140. Specific elements and procedures of the imager 100′ are described in detail below.

The CCD sensor 110 is preferably configured to include a two dimensional array of charge coupled devices. Preferably by having the CCD sensor 110 as a two dimensional sensor, the direct imaging system 100′ is capable of simultaneously imaging either an entire area of the DUT 140 or just a portion of the DUT 140 (depending on the size of the DUT 140) for photon emissions emitted by the DUT 140. By simultaneously imaging the entire DUT 140, the CCD sensor 110 allows the direct imaging system 100′ to complete the detection process in most cases well under one minute and in some cases in only twenty-five seconds. In this preferred embodiment, the CCD sensor 110 is manufactured by Sony Corporation having the model number ICX 038DLA. It will be apparent to those skilled in the art to utilize CCD sensors having different model numbers or from different manufacturers. In an alternate embodiment, the CCD sensor 110 comprises cooled charge coupled devices. By having the charge coupled devices within the CCD sensor 110 cooled, background noise is reduced and signal clarity is maximized.

The microlens array 130′ is coupled to the CCD sensor 110. The microlens array 130′ directs the photon emissions 160 to each of the discrete sensors within the CCD sensor 110 such that the photon emissions 160 are detected without the use of magnifying optics such as multiple lenses and the like. A taper 120′ is coupled to the microlens array 130′. By utilizing the microlens array 130′ and the taper 120′, the CCD 110 directly senses and locates the photon emissions 160 without requiring them to pass through any magnifying optics. Preferably, the taper 120′ utilizes fiber optic lines to pass the photon emissions 160 from the DUT 140 to the CCD sensor 110. By utilizing fiber optic lines, signal loss due to the taper 120′ is minimized and for practical purposes altogether eliminated.

Preferably, the taper 120′ optimizes the resolution of the CCD sensor 110 over a predetermined area of the DUT 140. For example, by utilizing a larger area of the CCD sensor 110 over a smaller area of interest on the DUT 140, the taper 120′ optimizes the resolution of the CCD sensor 110 to match the area of interest on the DUT 140. The micro lens array 130′ directs the photon emissions 160 from the taper 120′ to the CCE sensor 110.

As shown in FIG. 1B, the taper 120′ is preferably positioned at a predetermined distance 170′ from the DUT 140. The predetermined distance 170′ is selectively adjustable via the imaging system 100′ . As the predetermined distance 170′ increases, a larger viewable area of the DUT 140 is observed by the imager 100′. Similarly, as the distance 170′ increases, the effective magnification of the DUT 140 decreases which allows the same larger viewable area of the DUT 140 to be observed at a decreased resolution. Likewise, as the distance 170′ decreases, there is a smaller viewable area of the DUT 140 is observed by the imager 100′, an increased effective magnification of the DUT 140, and an increase in resolution of the DUT 140.

As shown in FIG. 1B, the imager 100′ is capable of efficiently detecting and locating photon emissions 160 emitted from the DUT 140. The CCD sensor 110, the micro lens array 130′ and the taper 120′ are preferably optimized relative to each other. Further, the CCD sensor 110, the micro lens array 130′ and the taper 120′ also allow the imager 100′ to increase or decrease magnification of the DUT 140 by merely changing the predetermined distance 170′ and without requiring different lenses.

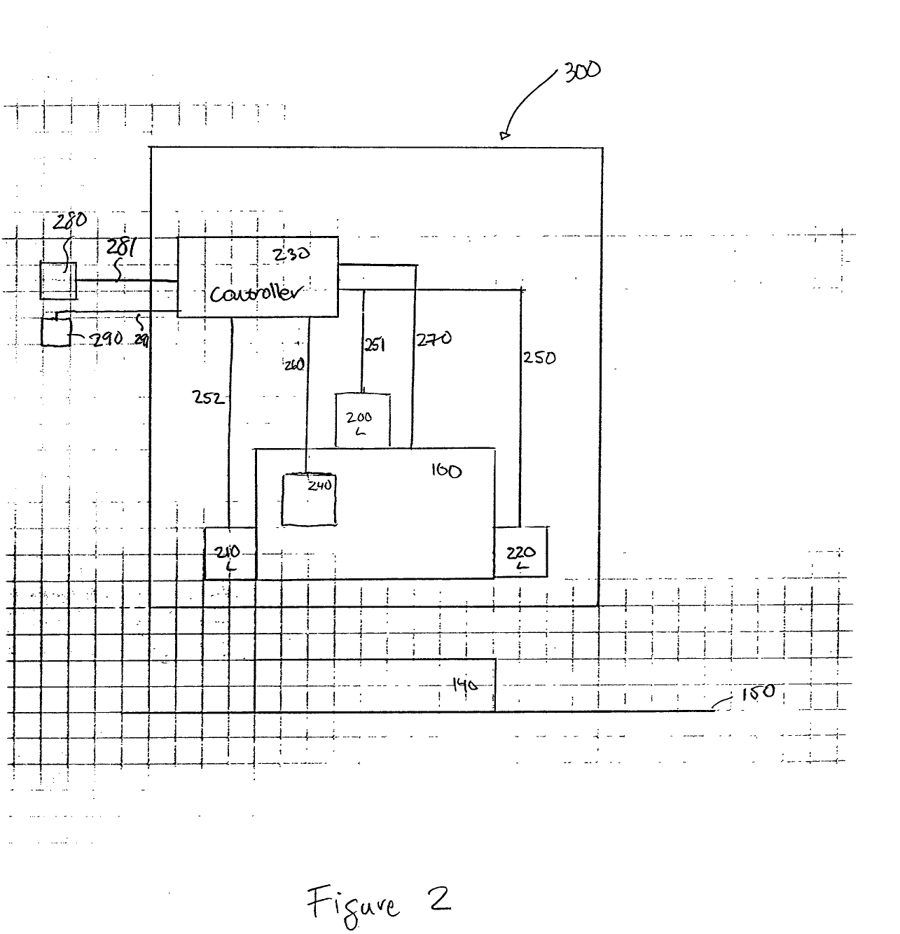

FIG. 2 illustrates a side view of internal components within an imaging head unit 300 of the preferred embodiment. For the sake of clarity and simplicity, common elements in FIGS. 1 and 2 also share common reference numerals. In particular, the direct imager 100, the DUT 140, and the surface 150 are common to both FIGS. 1 and 2. The imaging head unit 300 preferably includes the direct imager 100, an input device 280, a controller 230, a multi-directional device 240, a display 290, and laser guides 200, 210, and 220. The controller 300 is coupled to the multi-directional device 240, the input device 280, the display 290, and the laser guides 200, 210, and 220 through data links 260, 281, 291, 250, 251, and 252, respectively. The direct imager 100 is coupled to the controller 230 through data link 270.

Preferably, the laser guides 200, 210, and 220 are coupled to the direct imager 100 and are configured to appropriately align the direct imager 100 relative to the imaging head unit 300, the DUT 140, and the surface 150. In order to achieve optimal results in detecting photon emissions from the DUT 140, the direct imager 100 is preferably maintained at an optimal distance and an appropriate level relative to the DUT 140. The laser guides 200, 210, and 220, preferably sense a relative position of the direct imager 100 relative to the DUT 140 and the surface 150. Additionally, the laser guides 200, 210, and 220 also communicate the position of the direct imager 100 relative to the controller 230. By utilizing the laser guides 200, 210, and 220 in the preferred embodiment, the image head unit 300 is capable of accurately positioning the direct imager 100 in any desired location. In alternate embodiments, additional or fewer laser guides can be utilized without departing from the scope and spirit of the present invention.

The data link 270 preferably transmits image(s) from the direct imager 100 to the controller 230. Preferably, the controller 230 analyzes each image for clarity. The controller 230 also shows each image on the display 290. The user preferably is able to view each image on this display 290.

The multi-directional device 240 is coupled to the direct imager 100 and preferably positions the direct imager 100 relative to the DUT 140. The multi-directional device 240 is capable of tilting and moving the direct imager 100 in a variety of directions. Preferably, the controller 230 provides instructions to the multi-directional device 240 through the data link 260.

The input device 280 allows the user to communicate with the controller 230 through the data link 281. Through the input device 280, the user is preferably capable of controlling many aspects of a resulting image of the DUT 140. For example, the user is capable of manually focusing the image, enlarging the image, reducing the image, and viewing a different portion of the DUT 140 by moving the direct imager 100 through the multi-directional device 240.

In operation, the controller 230 preferably receives images from the direct imager 100. The controller 230 preferably analyzes these images and also displays them to the user via the display 290. The controller 230 receives instructions from the user through the input device 280. Based upon the analysis by the controller 230 and information from the input device 280, the controller 230 determines an appropriate target position for the direct imager 100 relative to the DUT 140 and the surface 150. The controller 230 also directs the multi-directional device 240 to position the direct imager 100 based upon a present location of the direct imager 100 as determined by the laser guides 200, 210, and 220, and the appropriate target position.

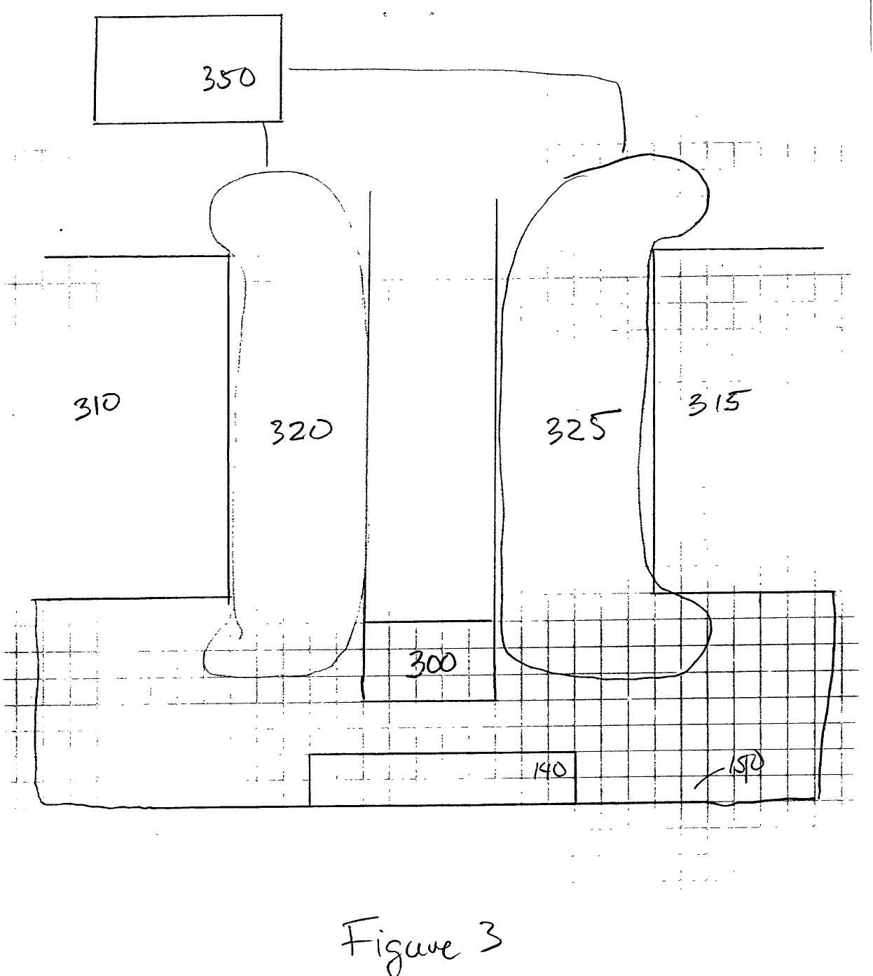

FIG. 3 illustrates a side view of the imaging head unit 300 with stabilizers 320 and 325 configured to hold the imaging head unit 300 within a tester. For the sake of clarity and simplicity, common elements in FIGS. 2, and 3 also share common reference numerals. In particular, the imaging head unit 300, the DUT 140, and the surface 150 are common to both FIGS. 2 and 3.

The stabilizers 320 and 325 are coupled to the imaging head 300. The stabilizers 320 and 325 are preferably configured to selectively expand and decrease in volume and are coupled to a controller 350. In this preferred embodiment, the stabilizers 320 and 325 are filled with air. Further, the stabilizers 320 and 325 are capable of securely holding the imaging head 300 within against walls 310 and 315 within the tester, respectively. In addition to securely holding the imaging head 300, the stabilizers 320 and 325 also further isolate the imaging head 300 from vibrations being transmitted through the tester. The controller 350 preferably instructs the stabilizers 320 and 325 either to maintain present position, expand in volume, or decrease in volume. The stabilizers 320 and 325 also utilize a safety feature which prevents them from over-inflating which could potentially cause damage to themselves or an adjacent wall such as the walls 310 and 315.

In alternate embodiments, there can be greater and fewer number of stabilizers to securely position the imaging head 300. Further, the stabilizers can be filled with other media besides air.

In operation, prior to installing the imaging head 300 within the tester, the stabilizers 320 and 325 are initially in a reduced state. In this particular example, the DUT 140, the surface 150, and the walls 310 and 315 are shown for exemplary purposes and are not intended to be part of the present invention. In this reduced state, the stabilizers 320 and 325 are preferably at their reduced volume. To place the imaging head 300 into the tester, the stabilizers 320 and 325, in their reduced state, are preferably placed between the walls 310 and 315 such that the imaging head 300 is positioned in relative proximity to the DUT 140. Next, the controller 350 instructs the stabilizers 320 and 325 to increase in volume. As the size of the stabilizers 320 and 325 grow, the stabilizers 320 and 325 preferably contact the walls 310 and 315, respectively. The stabilizers 320 and 325 preferably continue to grow until the imaging head 300 and the stabilizers 320 and 325 are securely coupled to the walls 310 and 315 of the tester. The stabilizers 320 and 325 are designed with the safety feature which prevents them from over-inflating and damaging themselves or the walls 310 and 315 within the tester. Once the stabilizers 320 and 325 are securely coupled to the walls 310 and 315 of the tester, the imaging head 300 preferably performs internal adjustments to appropriately position itself relative to the DUT 140.

To remove the imaging head 300 from within the tester, the stabilizers 320 and 325 preferably decrease in volume and return to their reduced state. Once the stabilizers 320 and 325 reach their reduced state, the imaging head 300 is capable of being removed from the tester.

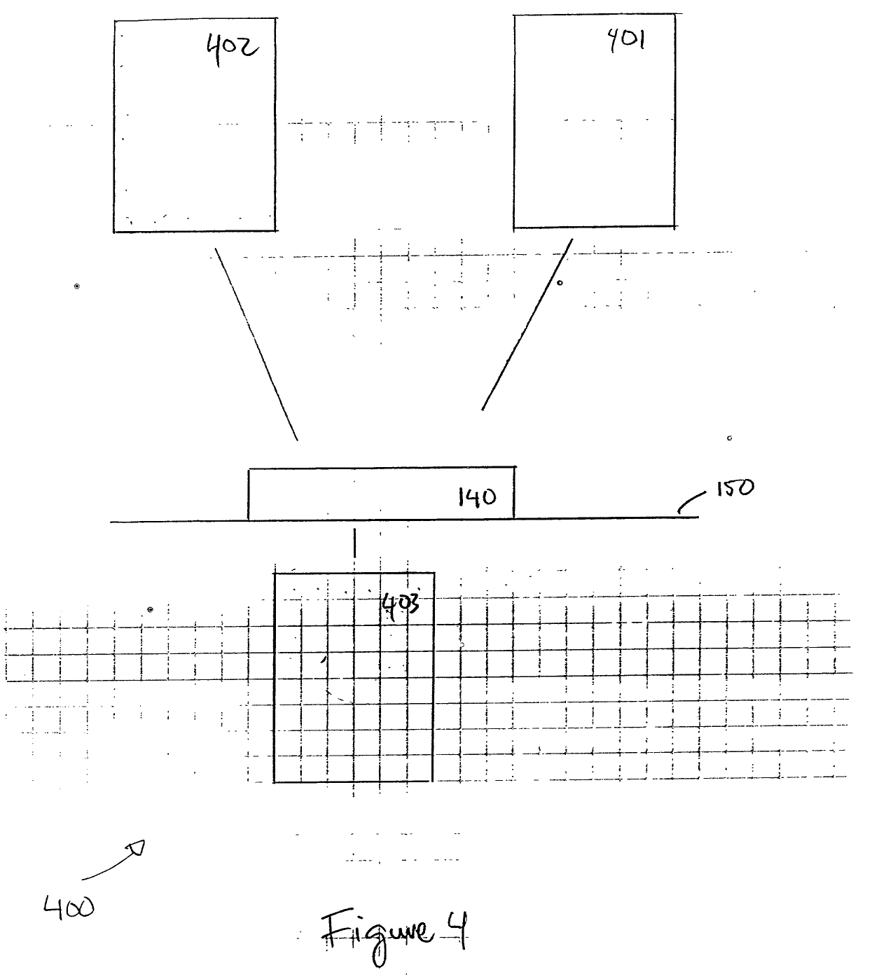

FIG. 4 illustrates an imaging system 400 which utilizes more than one imaging head. For the sake of clarity and simplicity, common elements in FIGS. 2, 3, and 4 also share common reference numerals. In particular, the DUT 140, and the surface 150 are common to FIGS. 2, 3, and 4. The imaging system 400 preferably includes imaging heads 401, 402, and 403. Each of the imaging heads 401, 402, and 403, are similar to the imaging head 300 described above and shown in FIG. 3.

The imaging heads 401 and 402 are preferably configured to perform front-side imaging on the DUT 140. Although both imaging heads 401 and 402 perform front-side imaging, the resultant image from the imaging head 401 preferably differs from the resultant image from the imaging head 402 due to a different perspective between the DUT 140 and the imaging heads 401 and 402. The imaging head 403 is preferably configured to perform back-side imaging on the DUT 140. The resultant images from the imaging heads 401, 402, and 403 illustrate a three-dimensional perspective.

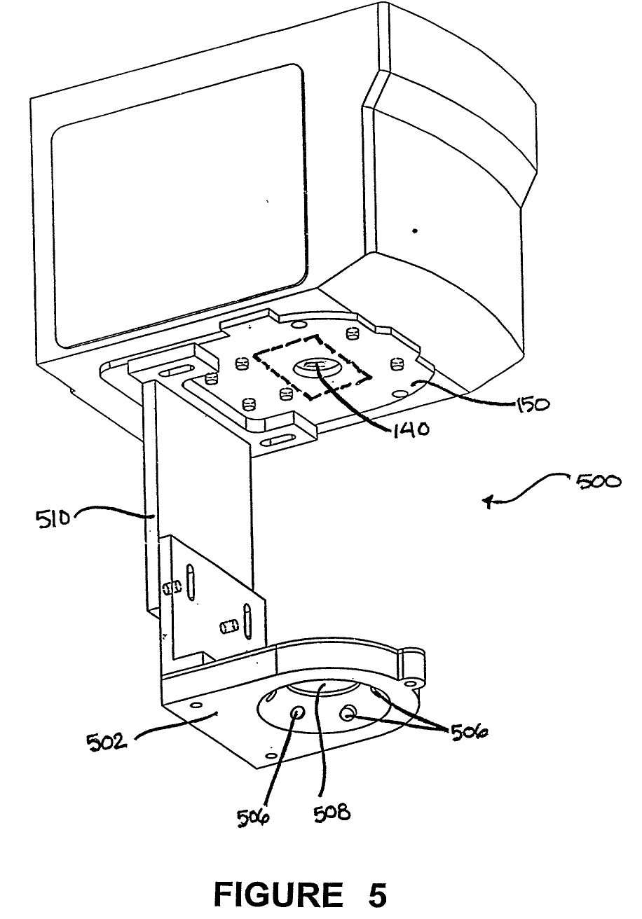

FIG. 5 illustrates a light emitting diode (LED) ring light assembly 500. The DUT 140, and the surface 150 are common to FIGS. 2, 3, 4, and 5. Preferably, the LED ring light assembly 500 evenly illuminates the DUT 140. The LED ring light assembly 500 preferably includes a cover 502, a plurality of LEDs 506, and a stand 510. The cover 502 is preferably coupled to the stand 510 and houses the plurality of LEDs 506. The cover 502 also has an opening 508 which is preferably configured to accept the micro lens array 130 (FIG. 1A) of the direct imager 100 (FIG. 1A). The stand 510 is coupled between the cover 502 and the surface 150 and allows a distance between the cover 502 and the surface 150 to be adjusted.

In operation, the plurality of LEDs 506 illuminate the DUT 140. The distance between the plurality of LEDs 506 and the DUT 140 is adjustable by moving the stand 510. The plurality of LEDs 506 preferably emit a light wavelength of approximately 400 to 1500 nanometers. By utilizing the plurality of LEDs 506 in the ring light assembly 500, the DUT 140 is evenly illuminated which optimizes performance of the direct imager 100 (FIG. 1A).

The present invention has been described in terms of specific embodiments incorporating details to facilitate the understanding of the principles of construction and operation of the invention. Such reference herein to specific embodiments and details thereof is not intended to limit the scope of the claims appended hereto. It will be apparent to those skilled in the art that modifications can be made in the embodiments chosen for illustration without departing from the spirit and scope of the invention.

Specifically, it will be apparent to one of ordinary skill in the art that the device of the present invention could be implemented in several different ways and the apparatus disclosed above is only illustrative of the preferred embodiment of the invention and is in no way a limitation. For example, it would be within the scope of the invention to vary the dimensions disclosed herein. In addition, it will be apparent that the various aspects of the above-described invention can be utilized singly or in combination with one or more of the other aspects of the invention described herein. In addition, the various elements of the present invention could be substituted with other elements.

What is claimed is:

1. An apparatus for analyzing a device, the apparatus comprising:
a. a sensor configured for detecting photon emissions from the device;
b. a taper coupled to the sensor for directing the photon emissions from the device to the sensor,
wherein the photon emissions are directly transmitted from the taper to the sensor.

2. The apparatus according to claim 1 wherein the sensor is a charge coupled device.

3. The apparatus according to claim 1 wherein the sensor is a two dimensional charge coupled device.

4. The apparatus according to claim 1 further comprising a micro lens array coupled to the taper wherein the micro lens array directs the photon emissions from the device to the taper and is positioned between the taper and the device.

5. The apparatus according to claim 1 further comprising a light ring coupled to the sensor for evenly illuminating the device.

6. The apparatus according to claim 1 further comprising a positioning system coupled to the sensor, wherein the positioning system comprises:
a. a controller;
b. a plurality of laser guides coupled to the controller for determining a location of the sensor relative to the device; and
c. a multi-direction device coupled to the controller for positioning the sensor relative to the device,
wherein the controller receives the location from the plurality of laser guides and selectively instructs the multi-directional device to move the sensor.

7. The apparatus according to claim 1 further comprising a base coupled to the sensor and configured for supporting the device.

8. An apparatus configured for analyzing photon emissions from a device, the apparatus comprising:
a. a sensor configured for detecting the photon emissions from the device;
b. a taper coupled to the sensor for transmitting the photon emissions to the sensor; and
c. a micro lens array coupled to the taper for directing the photon emissions from the device to the taper,
wherein the sensor is configured to directly detect the photon emissions from the device.

9. The apparatus according to claim 8 wherein the sensor is a charge coupled device.

10. The apparatus according to claim 9 wherein the sensor is a two dimensional charge coupled device.

11. The apparatus according to claim 8 further comprising a light ring coupled to the sensor for evenly illuminating the device.

12. The apparatus according to claim 8 further comprising a positioning system coupled to the sensor, wherein the positioning system comprises:
a. a controller;
b. a plurality of laser guides coupled to the controller for determining a location of the sensor relative to the device; and
c. a multi-direction device coupled to the controller for positioning the sensor relative to the device,
wherein the controller receives the location from the plurality of laser guides and selectively instructs the multi-directional device to move the sensor.

13. The apparatus according to claim 8 further comprising a base coupled to the sensor and configured for supporting the device.

14. A system configured to detect and locate photon emissions emitted from a device, the system comprising:
a. a first imager comprising a first CCD sensor and a first taper coupled to the first CCD sensor wherein the first taper is configured to transmit the photon emissions from the device to the first CCD sensor;
b. a second imager comprising a second CCD sensor and a second taper coupled to the second CCD sensor wherein the second taper is configured to transmit the photon emissions from the device to the second CCD sensor; and
c. a third imager comprising a third CCD sensor and a third taper coupled to the third CCD sensor wherein the third taper is configured to transmit the photon emissions from the device to the third CCD sensor.

15. A method of detecting and locating a photon emission from a device comprising the steps of:
a. capturing the photon emission from the device with an imager; and
b. detecting the photon emission utilizing a sensor within the imager wherein the photon emission does not pass through a series of lenses.

16. The method according to claim 15 wherein the sensor is a charge coupled device.

17. The method according to claim 15 further comprising magnifying an area of the device being detected without changing optical components within the imager.

18. The method according to claim 15 further comprising transmitting the photon emission from the device to the sensor via a taper to improve an effective resolution of the device without utilizing optical elements.

19. The method according to claim 18 wherein the taper utilizes fiber optics to transmit the photon emission to the sensor.

20. The method according to claim 18 further comprising directing the photon emission from the device to the taper through a micro lens array wherein a distance between the taper and the micro lens array is fixed.

21. The method according to claim 15 further comprising positioning the imager in a location relative to the device.

22. The method according to claim 21 further comprising sensing the location of the imager.
